(19) United States
(12) Patent Application Publication
(10) Pub. No.: US 2006/0160337 A1
(43) Pub. Date: Jul. 20, 2006

(54) Method of manufacturing a hemisperical grain silicon layer and method of manufacturing a semiconductor device using the same

(76) Inventors: Young-Jin Kim, Gyeonggi-do (KR); Hyeon-Deok Lee, Seoul (KR); Seok-Woo Nam, Gyeonggi-do (KR); Yong-Jae Lee, Incheon (KR); Hyun-Seok Lim, Gyeonggi-do (KR); Wan-Goo Hwang, Gyeonggi-do (KR); Jin-Il Lee, Gyeonggi-do (KR); Jung-Hwan Oh, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/323,999

(22) Filed: Dec. 29, 2005

(30) Foreign Application Priority Data
Dec. 30, 2004 (KR) 2004-116453

(51) Int. Cl. H01L 21/20; H01L 21/36

(52) U.S. Cl. 438/507

(57) ABSTRACT

In a method of manufacturing a capacitor including a hemispherical grain (HSG) silicon layer, after forming a storage electrode electrically coupled to a contact region of a substrate, the HSG silicon layer is formed on the storage electrode by providing a first gas including silicon and a second gas onto a surface of the storage electrode with a volume ratio of about 1.0:0.1 to about 1.0:5.0. A dielectric layer and a plate electrode are sequentially formed on the HSG silicon layer. A grain size of the HSG silicon layer may be easily adjusted and abnormal growths of the HSG at a lower portion of the storage electrode may be suppressed. Therefore, the HSG silicon layer may be uniformly formed on the storage electrode, and a structural stability of the storage electrode may be improved to prevent electrical defects of the capacitor.

### CROSS-REFERENCE TO RELATED APPLICATIONS

This application claims priority under 35 USC § 119 to Korean Patent Application No. 2004-116453 filed on Dec. 30, 2004, the contents of which are herein incorporated by reference in their entirety.

### BACKGROUND OF THE INVENTION

1. Field of the Invention

Example embodiments of the present invention relate to a method of manufacturing a semiconductor device. More particularly, example embodiments of the present invention relate to a method of manufacturing a hemispherical grain (HSG) silicon layer and a method of manufacturing a semiconductor device including the HSG silicon layer.

2. Description of the Related Art

Generally, semiconductor memory devices such as a dynamic random access memory (DRAM) and a static random access memory (SRAM) are capable of reading data stored therein or writing other data for storage, such as data or programming commands. Each of the memory devices mainly includes at least one transistor and one capacitor. For example, a 16-megabit DRAM (16 Mb DRAM) is a large-scale integrated circuit including 16 million transistors and 16 million capacitors per unit chip. Conventionally, a capacitor employed for the DRAM device includes a storage electrode, a dielectric layer and a plate electrode, etc.

In order to improve a capacity of a semiconductor memory device including the capacitor, it is important to enhance a capacitance of the capacitor. Presently, the capacitor has a cylindrical structure having inner and outer areas of the capacitor as effective areas in order to achieve a desired capacitance of the capacitor. A method of increasing a height of the storage electrode of the capacitor and raising a surface area of the capacitor by forming a hemispherical grain (HSG) silicon layer on the storage electrode has been widely used in order to augment a capacitance of the capacitor.

A method of manufacturing a capacitor including the HSG silicon layer is disclosed in Korean Laid-Open Patent Publication No. 2003-3418, U.S. Pat. No. 6,413,813 issued to Jeng Erick, U.S. Pat. No. 6,403,411 issued to Chih-Hsun Chu, et al., etc.

FIGS. 1A to 1C are cross-sectional views illustrating a conventional method of manufacturing a capacitor including an HSG silicon layer.

Referring to FIG. 1A, an insulating interlayer 10 including an oxide is formed on a semiconductor substrate 5. Then, the insulating interlayer 10 is partially etched by a photolithographic etching process to form a plurality of openings 15 exposing contact regions of the semiconductor substrate 5.

A first conductive layer including polysilicon doped with impurities or metal is formed to fill up the plurality of the openings 15. The first conductive layer is partially etched until the insulating interlayer 10 is exposed by a chemical mechanical polishing (CMP) process or an etch back process to thereby form a plurality of contacts 20 filling up the plurality of the openings 15.

Referring to FIG. 1B, after a mold oxide layer 25 is formed on the insulating interlayer 10 having the contacts 20, the mold oxide layer 25 is partially etched by a photolithographic etching process to thereby form a plurality of contact holes 30 exposing the contacts 20, respectively.

A second conductive layer is formed on the exposed contact 20, an inner sidewall of the contact holes 30 and the mold oxide layer 25, using polysilicon doped with impurities. The second conductive layer is removed until the mold oxide layer 25 is exposed by a CMP process, to form a plurality of storage electrodes 35 making contact with the contacts 20, respectively.

Referring to FIG. 1C, after a plurality of the cylindrical storage electrodes 35 is formed by removing the mold oxide layer 25, a plurality of HSG silicon layers 40 is formed on the plurality of the storage electrodes 35. A silane (SiH₄) gas or a disilane (Si₂H₆) gas is provided onto the storage electrodes 35 at a temperature of about 500 to 600° C. so that the HSG silicon layers 40 grow from the face of the storage electrode 35. Dielectric layers 45 and a plate electrode 50 are sequentially formed on the HSG silicon layers 40 to complete capacitors 55.

However, when the capacitors 55 including the above-described HSG silicon layers 40 are formed, the HSG silicon layers 40 grow irregularly from inner sidewalls of the cylindrical storage electrodes 35, which causes a plurality of the HSG silicon layers 40 growing from sidewalls of the storage electrodes 35 to be physically connected to each other. Further, abnormal growths of the HSG silicon layers 40 on a bottom portion of the storage electrodes 35 deteriorate electrical characteristics of the capacitors 55 and structural stabilities of the storage electrodes 35. In addition, even though the HSG silicon layers are 40 formed on the storage electrodes 35, the capacitances of the capacitors 55 increase by no more than about 10 to 15 percent because of the abnormal growths of the HSG silicon layers 40. Embodiments of the disclosure address these and other limitations in the prior art.

### SUMMARY OF THE INVENTION

Example embodiments of the present invention provide methods of manufacturing a hemispherical grain silicon layer. Example embodiments of the present invention also provide methods of manufacturing capacitors having improved electrical characteristics and increased capacitances. Example embodiments of the present invention also provide methods of manufacturing semiconductor devices including the capacitors.

According to one aspect of the present invention, there is provided a method of manufacturing a capacitor having improved structural stability and electrical characteristics. In the method of manufacturing the capacitor, a storage electrode electrically connected to a contact region of a substrate is formed. An HSG silicon layer is formed on the storage electrode by providing a mixture gas including a first gas containing silicon and a second gas onto the storage electrode. A dielectric layer is formed on the HSG silicon layer. Then, a plate electrode is formed on the dielectric layer.

In an example embodiment of the present invention, the first gas includes silane or disilane, and the second gas includes an inactive gas such as a nitrogen (N₂) gas, a helium (He) gas or an argon (Ar) gas.

In an example embodiment of the present invention, a volume ratio between the first gas and the second gas is in a range of about 1.0:0.1 to 1.0:5.0, and the storage electrode has a cylindrical shape, and the HSG silicon layer is formed on an inside of the storage electrode.

In an example embodiment of the present invention, a pad making contact with the contact region is formed. A mold layer is formed on the pad. The mold layer is partially etched to form a hole exposing the pad. A conductive layer is formed on the pad, an inner sidewall of the hole and the mold layer. The conductive layer is partially removed. Thus, the storage electrode is completed. Here, the hole is formed by forming a mask layer on the mold layer and etching the mask layer to form a mask for defining the storage electrode on the mold layer.

According to one aspect of the present invention, there is provided a method of manufacturing a capacitor having improved structural stability and electrical characteristics. In the method of manufacturing the capacitor, a pad is formed on a substrate having a contact region, and the pad is electrically connected to the contact region. Then, a storage electrode is formed on the pad. An HSG silicon layer is formed on the storage electrode by providing a mixture gas of a gas containing silicon and hydrogen, and an inactive gas onto the storage electrode. Then, a dielectric layer and a plate electrode are formed on the HSG silicon layer.

In an example embodiment of the present invention, the gas containing silicon and hydrogen includes a silane gas or a disilane gas. The inactive gas includes a nitrogen gas, a helium gas or an argon gas. Here, a volume ratio between the gas containing the silicon and hydrogen and the inactive gas is in a range of about 1.0:0.1 to 1.0:5.0.

According to one aspect of the present invention, there is provided a method of manufacturing a semiconductor device including a capacitor having improved structural stability and electrical characteristics. In the method of manufacturing the semiconductor device, after a contact region is formed on a semiconductor substrate, a pad is formed to be electrically connected to the contact region. Then, after at least one insulating interlayer is formed on the pad, a mold layer is formed on the insulating interlayer. The mold layer and the insulating interlayer are partially etched to thereby form a contact hole exposing the pad. A storage electrode is formed on the pad and an inner sidewall of the contact hole. Then, an HSG silicon layer is formed on the storage electrode by providing a mixture gas including a gas containing silicon and an inactive gas onto the storage electrode. A dielectric layer and a plate electrode are sequentially formed on the HSG silicon layer.

In an example embodiment of the present invention, the gas containing silicon and hydrogen includes a silane gas or a disilane gas. The inactive gas includes a nitrogen gas, a helium gas or an argon gas. Here, a volume ratio between the gas containing silicon and hydrogen and the inactive gas is in a range of about 1.0:0.1 to 1.0:5.0.

According to the present invention, an HSG silicon layer may be formed on a storage electrode using a gas mixture of a gas containing silicon with an inactive gas so that a grain size of an HSG silicon layer may be easily adjusted and abnormal growths of HSG grains may be suppressed at a lower portion of the storage electrode. Therefore, the HSG silicon layer may be uniformly formed on the storage electrode to thereby improve a structural stability of the storage electrode and decrease electrical defects of a capacitor.

In addition, when an HSG silicon layer having a uniform grain size is employed in a DRAM device, the electrical characteristics of the capacitor may be improved and a capacitance of the capacitor may be increased to an extent of above 20 percent.

### BRIEF DESCRIPTION OF THE DRAWINGS

The above and other features and advantages of the present invention will become more apparent by describing in detailed example embodiments thereof with reference to the accompanying drawings, in which:

FIGS. 1A to 1C are cross-sectional views illustrating a conventional method of forming a capacitor;

FIGS. 2A to 2G are cross-sectional views illustrating a method of manufacturing a semiconductor device including a capacitor in accordance with an example embodiment of the present invention;

FIGS. 3A to 3C are electron microscopic pictures illustrating growths of conventional HSG silicon layers relative to feeding times of source gases;

FIGS. 4A to 4D are electron microscopic pictures illustrating growths of HSG silicon layers relative to volumes of inactive gases in accordance with example embodiments of the present invention;

FIGS. 5A and 5B are electron microscopic pictures illustrating an HSG silicon layer formed by providing a mixture gas including a silane gas and a nitrogen gas for about 13 minutes in accordance with an example embodiment of the present invention;

FIGS. 6A and 6B are electron microscopic pictures illustrating an HSG silicon layer formed by providing a mixture gas including a silane gas and a nitrogen gas for about 15 minutes in accordance with an example embodiment of the present invention;

FIG. 7 is a graph illustrating thicknesses of storage electrodes and HSG silicon layers relative to feeding times of source gases in accordance with a conventional method and example embodiments of the present invention; and

FIG. 8 is a graph illustrating accumulation distributions of electrical defects generated in capacitors having HSG silicon layers in accordance with example embodiments of the present invention.

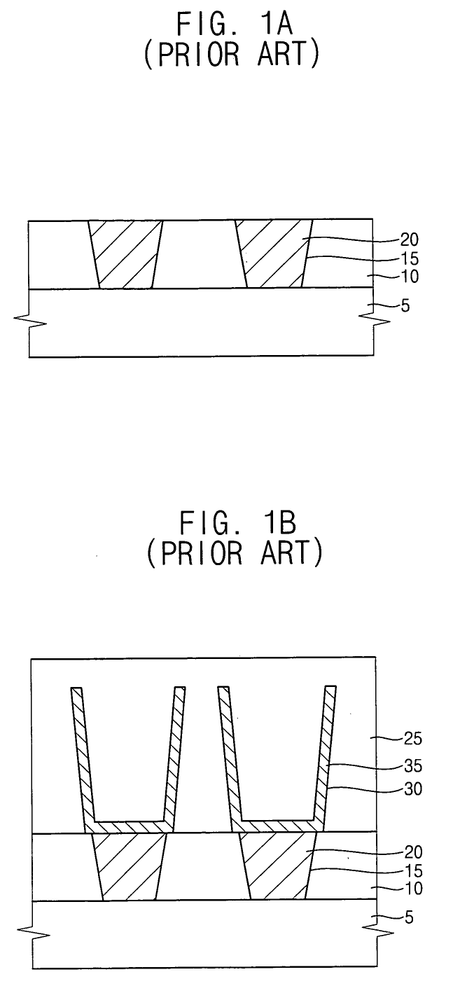

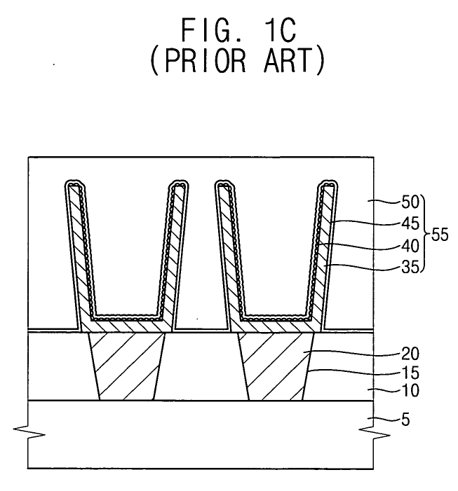

### DESCRIPTION OF THE EMBODIMENTS

The invention is described more fully hereinafter with reference to the accompanying drawings, in which embodiments of the invention are shown. The present invention may, however, be embodied in many different forms and should not be construed as limited to the embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

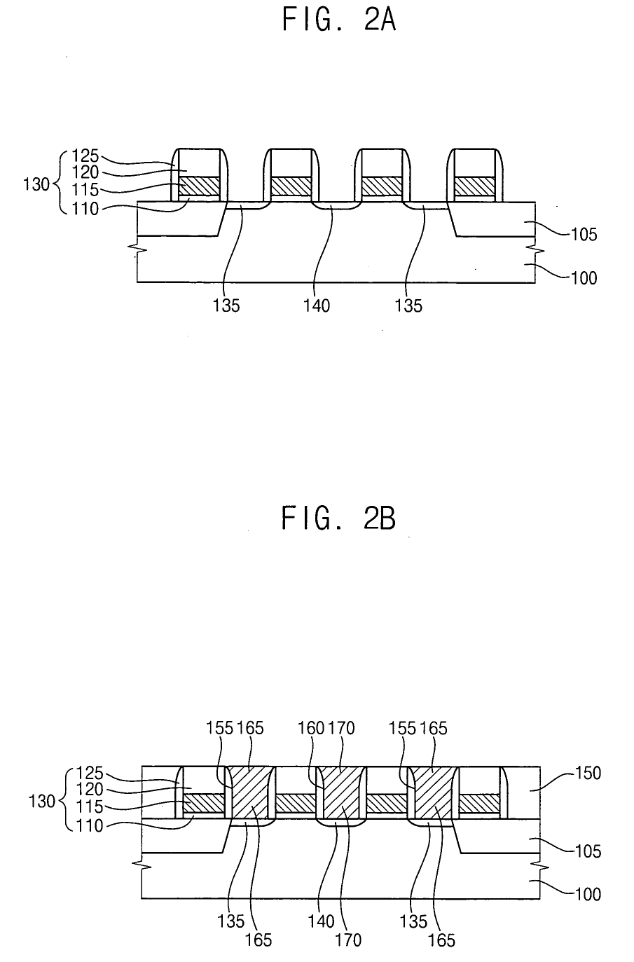

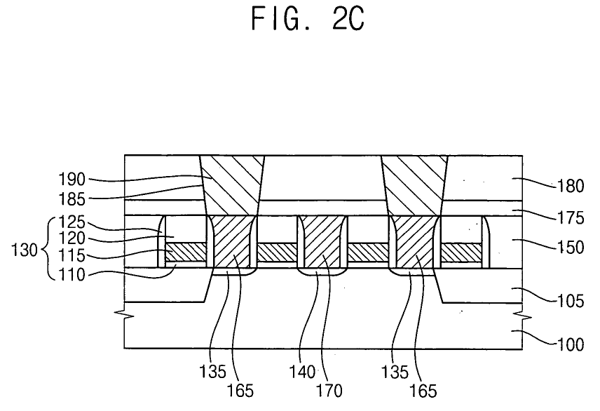

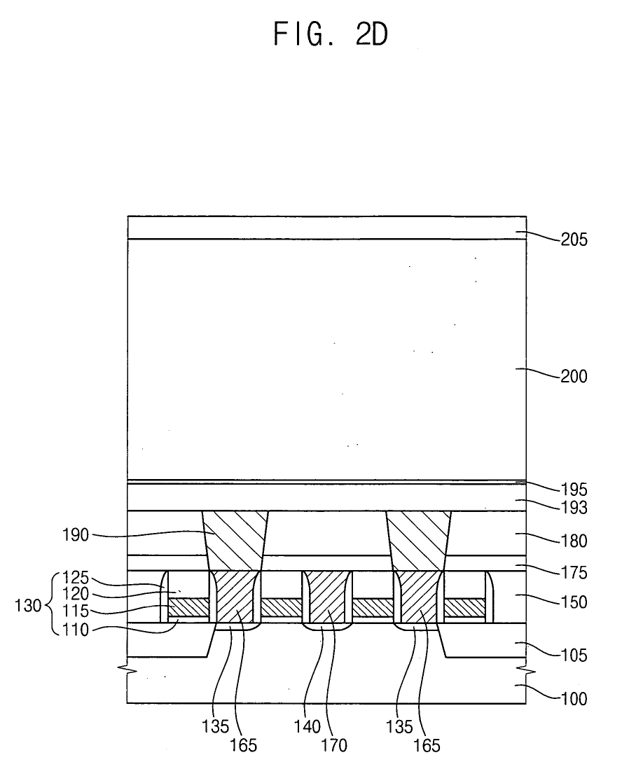

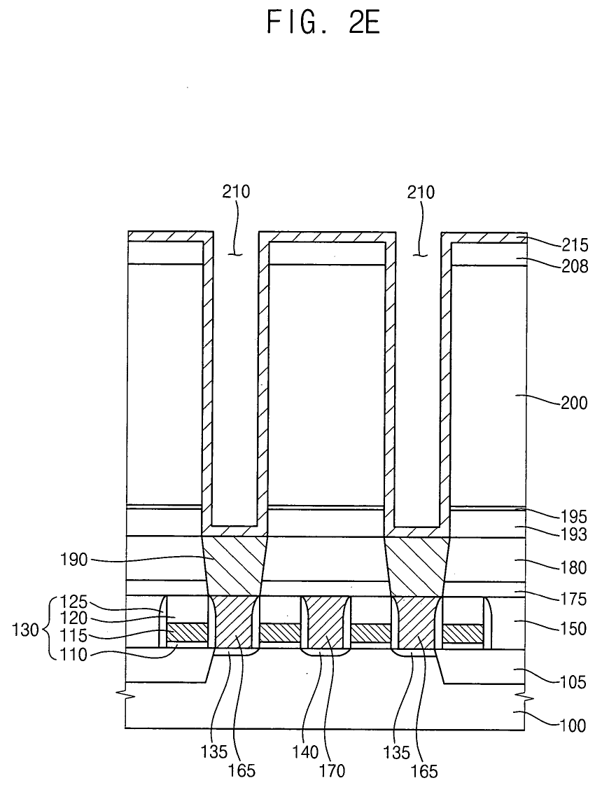

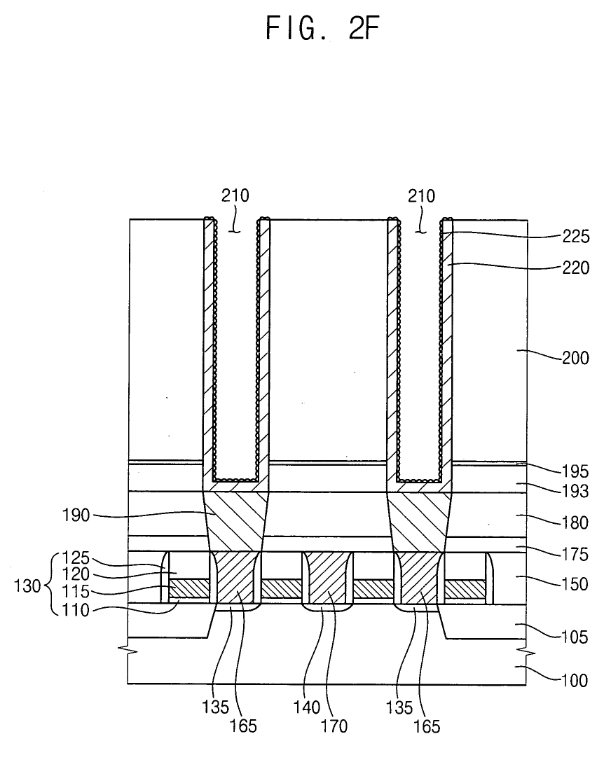

FIGS. 2A to 2G are cross-sectional views illustrating a method of manufacturing a semiconductor device including a capacitor in accordance with an example embodiment of the present invention.

FIG. 2A is a cross-sectional view illustrating a step of forming word lines on a semiconductor substrate 100.

Referring to FIG. 2A, an isolation layer 105 is formed on the semiconductor substrate 100 by an isolation process such as a shallow trench isolation (STI) process. When the isolation layer 105 is formed on the semiconductor substrate 100, the semiconductor substrate 100 is divided into an active region and a field region.

A gate insulation layer is then formed on the semiconductor substrate 100 having the isolation layer 105 thereon by, for example, a chemical vapor deposition (CVD) process or a thermal oxidation process. The gate insulation layer may be formed using an oxide such as silicon oxide. The gate insulation layer may be patterned to form a gate insulation layer pattern 110 on the active region of the semiconductor substrate 100.

Next, a first conductive layer and a first mask layer are sequentially formed on the gate insulation layer. The first conductive layer may be formed using polysilicon doped with impurities, metal or metal nitride. The first conductive layer will be patterned to form a gate electrode 115 on the gate insulation layer pattern 110.

In an example embodiment of the present invention, the first conductive layer may have a polycide structure that includes a doped polysilicon film and a metal silicide film.

The first mask layer may be patterned to form a gate mask 120 on the gate electrode 115. The first mask layer may be formed using a material having an etching selectivity relative to a first insulating interlayer 150 (see FIG. 2B). For example, the first mask layer is formed using a nitride such as silicon nitride when the first insulating interlayer 150 is formed using an oxide such as silicon oxide.

Referring back to FIG. 2A, after a first photoresist pattern (not shown) is formed on the first mask layer, the first mask layer, the first conductive layer and the gate insulation layer are sequentially etched using the first photoresist pattern as an etching mask. Thus, the gate insulation layer pattern 110, the gate electrode 115 and the gate mask 120 are formed on the semiconductor substrate 100 in serial.

In an example embodiment of the present invention, the first mask layer may be patterned using the first photoresist pattern as an etching mask to thereby initially form the gate mask 120 on the first conductive layer. After the first photoresist pattern is removed by an ashing process and/or a stripping process, the first conductive layer and the gate insulation layer may be etched in order, using the gate mask 120 as an etching mask, thereby forming the gate insulation layer pattern 110 and the gate electrode 115 on the semiconductor substrate 100.

Next, gate spacers 125 may be formed. A first insulation layer is formed on the semiconductor substrate 100 to cover the gate mask 120. The first insulation layer may be anisotropically etched to form a gate spacer 125 on sidewalls of the gate mask 120 and the gate electrode 115. The first insulation layer may be formed using a nitride such as silicon nitride. Thus, gate structures 130 are formed on the semiconductor substrate 100. Each of the gate structures 130 includes the gate insulation pattern 110, the gate electrode 115, the gate mask 120 and the gate spacer 125.

Impurities are implanted into portions of the semiconductor substrate 100 exposed between the gate structures 130 using the gate structures 130 as ion implantation masks. A heat treatment process is performed on the semiconductor substrate 100 to form a first contact region 135 and a second contact region 140 at the exposed portions of the semiconductor substrate 100. The first and the second contact regions 135 and 140 may correspond to source/drain regions. As a result, word lines having the first and second contact regions 135 and 140 and the gate structures 130 are formed on the semiconductor substrate 100. Each of the word lines positioned in the active region is electrically insulated from an adjacent word line by the gate mask 120 and the gate spacer 125.

Each of the first and the second contact regions 135 and 140 may respectively correspond to one of a capacitor contact region and a bit line contact region. The first pad 165 for a capacitor 245 (see FIG. 2G) makes electrical contact with the capacitor contact region. The second pad 170 for a bit line makes electrical contact with the bit line contact region. Thus, the first contact region 135 corresponds to the capacitor contact region whereas the second contact region 140 corresponds to the bit line contact region.

FIG. 2B is a cross-sectional view illustrating steps of forming the first insulating interlayer 150, the first pad 165 and the second pad 170.

Referring to FIG. 2B, the first insulating interlayer 150 is formed on the semiconductor substrate 100 to cover the word lines. The first insulating interlayer 150 may be formed using an oxide such as boro-phosphor silicate glass (BPSG), phosphor silicate glass (PSG), undoped silicate glass (USG), spin-on glass (SOG), high-density plasma chemical vapor deposition (HDP-CVD) oxide, etc.

An upper portion of the first insulating layer 150 may be planarized by a chemical mechanical polishing (CMP) process, an etch back process, a combination process of CMP and etch back or any other method to expose the gate structure 130. In an example embodiment of the present invention, the planarized first insulating interlayer 150 may have a height somewhat higher than that of the gate structure 130.

After a second photoresist pattern (not shown) is formed on the first insulating interlayer 150, the first insulating interlayer 150 may be partially etched using the second photoresist pattern as an etching mask to thereby form a first contact hole 155 and a second contact hole 160 through the first insulating interlayer 150. The first and the second contact holes 155 and 160 respectively expose the first and the second contact regions 155 and 160. The first and second contact holes 155 and 160 may be formed by an anisotropic etching process.

In the etching process for partially etching the first insulating interlayer 150 including the oxide, the first insulating interlayer 150 may be etched using an etching solution or an etching gas having a high etching selectivity relative to the gate mask 120 including the nitride. Therefore, the first and the second contact holes 155 and 160 may be self-aligned with respect to the gate structures 130. The first contact hole 155 exposes the first contact region 135 corresponding to the capacitor contact region, and the second contact hole 160 exposes the second contact region 140 corresponding to the bit line contact region.

Referring now to FIG. 2B, after the second photoresist pattern is removed using an ashing process and/or a stripping process, a second conductive layer is formed on the first insulating interlayer 150 to fill up the first and the second contact holes 155 and 160. The second conductive layer may be formed using polysilicon doped with impurities, metal or metal nitride.

The second conductive layer may be partially removed by a CMP process, an etch back process, a combination process of CMP and etch back, or any other method to expose the first insulating layer 150. Thus, the first pad 165 and the second pad 170 are formed to respectively fill up the first contact hole 155 and the second contact hole 160. Since the first and the second contact holes 155 and 160 are formed by the above-described self-alignment process, the first and the second pad 165 and 170 may correspond to self-aligned contact (SAC) pads. The first pad 165 makes electrical contact with the first contact region 135 corresponding to the capacitor contact region, whereas the second pad 170 makes electrical contact with the second contact region 140 corresponding to the bit line contact region.

FIG. 2C is a cross-sectional view illustrating steps of forming a second insulating interlayer 175, the bit line, a third insulating interlayer 180 and a fourth pad 190.

Referring to FIG. 2C, the second insulating interlayer 175 is formed on the first pad 165, the second pad 170 and the first insulating interlayer 150. The second insulating interlayer 175 may be formed using an oxide. The second insulating interlayer 175 may electrically insulate the first pad 165 from the bit line. For example, the second insulating interlayer 175 may be formed using BPSG, PSG, USG, SOG, HDP-CVD oxide, etc. Next, the second insulating interlayer 175 may be planarized by a CMP process, an etch back process, a combination process of CMP and etch back, or any other method.

After a third photoresist pattern (not shown) is formed on the planarized second insulating interlayer 175, the second insulating interlayer 175 is partially etched using the third photoresist pattern as an etching mask to thereby form a third contact hole (not shown) exposing the second pad 170 through the second insulating interlayer 175.

After the third photoresist pattern is removed by an ashing process and/or a stripping process, a third conductive layer and a second mask layer are sequentially formed on the second insulating interlayer 175 to fill up the third contact hole. The third conductive layer may be formed using doped polysilicon, metal or metal nitride. Alternatively, the third conductive layer may include a first film of titanium/titanium nitride and a second film of a tungsten compound. The second mask layer may be formed using a material having an etching selectivity relative to the second insulating interlayer 175 including the oxide. For example, the second mask layer may be formed using a nitride such as silicon nitride.

A fourth photoresist pattern (not shown) is formed on the second mask layer, and then the second mask layer and the third conductive layer are sequentially patterned using the fourth photoresist pattern as an etching mask, thereby forming a third pad (not shown) filling up the third contact hole and simultaneously forming the bit line including a bit line conductive layer pattern (not shown) and a bit line mask (not shown). The third pad electrically connects the bit line with the second pad 170. The bit line mask may protect the bit line conductive layer pattern in an etching process for forming a fifth contact hole 210 (see FIG. 2E).

Referring back to FIG. 2C, the second mask layer may be patterned using the fourth photoresist pattern as an etching mask so that the bit line mask is formed. After the fourth photoresist pattern is removed, the third conductive layer may be patterned using the bit line mask as an etching mask, thereby forming the bit line conductive layer pattern on the second insulating interlayer 175. The third pad filling up the third contact hole and the bit line conductive layer pattern may be formed simultaneously.

Next, bit line spacers (not shown) may be formed. A second insulation layer (not shown) is formed on the bit line and the second insulating interlayer 175. The second insulation layer is anisotropically etched to form a bit line spacer (not shown) on sidewalls of the bit line mask and the bit line conductive layer pattern. The bit line spacer may protect the bit line while forming a fourth pad 190 in a succeeding process. The bit line spacer may be formed using a material having an etching selectivity relative to the second insulating interlayer 175 and a third insulating interlayer 180. For example, the bit line spacer may include a nitride such as silicon nitride. The third insulating interlayer 180 including an oxide is formed on the second insulating interlayer 175 to cover the bit line having the bit line spacer. For example, the third insulating interlayer 180 is formed using BPSG, PSG, USG, SOG, HDP-CVD oxide, etc.

The third insulating interlayer 180 may be removed by a CMP process, an etch back process, a combination process of CMP and etch back or any other method to expose the bit line and planarize an upper portion of the third insulating interlayer 180.

After a fifth photoresist pattern (not shown) is formed on the third planarized insulating interlayer 180, the third insulating interlayer 180 and the second insulating interlayer 175 are partially etched using the fifth photoresist pattern as an etching mask. Accordingly, a fourth contact hole 185 exposing the first pad 165 is formed through the second and the third insulating interlayers 175 and 180. The fourth contact hole 185 may be self-aligned relative to the bit line spacer formed on the sidewall of the bit line.

A fourth conductive layer may be formed on the third insulating interlayer 180 to fill up the fourth contact hole 185. The fourth conductive layer may be removed by a CMP process, an etch back process, a combination process of CMP and etch back or any other method to expose the third insulating interlayer 180 and the bit line. Therefore, the fourth pad 190 is formed in the fourth contact hole 185. The fourth pad 190 contacting the first pad 165 may be formed using doped polysilicon, metal or metal nitride. The fourth pad 190 electrically connects the first pad 165 to a storage electrode 220 (see FIG. 2F) of the capacitor.

FIG. 2D is a cross-sectional view illustrating steps of forming a mold layer 200 and a third mask layer 205.

Referring to FIG. 2D, a fourth insulating interlayer 193 may be formed on the fourth pad 190, the bit line and the third insulating interlayer 180. The fourth insulating interlayer 193 may be formed using an oxide such as BPSG, PSG, USG, SOG, HDP-CVD oxide, etc. The fourth insulating interlayer 193 electrically insulates the bit line from the storage electrode 220.

An etch stop layer 195 may be formed on the fourth insulating interlayer 193. The etch stop layer 195 may be formed using a material having an etching selectivity relative to the fourth insulating interlayer 193 and the mold layer 200. For example, the etch stop layer 195 may be formed using a nitride such as silicon nitride.

In an example embodiment of the present invention, after an upper face of the fourth insulating interlayer 193 is planarized by a CMP process, an etch back process, a combination process of CMP and etch back, or any other method, the etch stop layer 195 may be formed on the planarized fourth insulating interlayer 193.

The mold layer 200 is formed on the etch stop layer 195. The mold layer 200 may be formed using an oxide such as BPSG, PSG, USG, SOG, HDP-CVD oxide, etc. The mold layer 200 may have a thickness of about 5,000 to 50,000 Å measured from an upper face of the etch stop layer 195. The thickness of the mold layer 200 may be adjusted in accordance with a desired capacitance of the capacitor 245. In an example embodiment of the present invention, the mold layer 200 may be directly formed on the fourth insulating interlayer 193 without a formation of the etch stop layer 195.

A third mask layer 205 may be formed on the mold layer 200. The third mask layer 205 may be formed using a material having an etching selectivity relative to the mold layer 200 including the oxide. For example, the third mask layer 205 may be formed using polysilicon. The third mask layer 205 may have a thickness of about 1,000 to 6,000 Å based on an upper face of the mold layer 200. As described above, the third mask layer 205 may have a thickness varied in accordance with the thickness of the mold layer 200.

In an example embodiment of the present invention, an upper face of the mold layer 200 may be planarized by a CMP process, an etch back process, a combination process of CMP and etch back or any other method. Next, the third mask layer 205 may be formed on the planarized mold layer 200.

FIG. 2E is a cross-sectional view illustrating steps of forming a fifth contact hole 210 and a fifth conductive layer 215.

Referring to FIG. 2E, after a sixth photoresist pattern (not shown) is formed on the third mask layer 205, the third mask layer 205 may be patterned using the sixth photoresist pattern as an etching mask to thereby form a storage mask 208 on the mold layer 200.

The mold layer 200, the etch stop layer 195 and the fourth insulating interlayer 193 may be partially etched using the storage mask 208 as an etching mask. Thus, the fifth contact hole 210 exposing the fourth pad 190 may be formed through the mold layer 200, the etch stop layer 195 and the fourth insulating interlayer 193. The sixth photoresist pattern may be consumed in a formation of the fifth contact hole 210. Optionally, the sixth photoresist pattern may be removed by an additional ashing process and/or a stripping process when the sixth photoresist pattern is not consumed in the formation of the fifth contact hole 210.

After the fifth contact hole 210 is formed, the semiconductor substrate 100 may be cleaned in order to remove etching residues generated in the formation of the fifth contact hole 210, and to remove a native oxide layer formed on the fourth pad 190.

A fifth conductive layer 215 may be formed on the fourth pad 190 exposed through the fifth contact hole 210, an inner sidewall of the fifth contact hole 210 and the storage mask 208. The fifth conductive layer 215 may be formed using doped polysilicon, metal, metal oxide or metal nitride.

Next, a sacrificial layer including an oxide may be formed on the fifth conductive layer 215 to fill up the fifth contact hole 210. The sacrificial layer may protect the storage electrode 220 in a formation of the storage electrode 220 and a succeeding etching process. The sacrificial layer may be formed using BPSG, USG, PSG, TEOS, HDP-CVD oxide, etc.

In an example embodiment of the present invention, an upper face of the sacrificial layer may be planarized by a CMP process, an etch back process, a combination process of CMP and etch back or any other method to expose the fifth conductive layer 215.

FIG. 2F is a cross-sectional view illustrating steps of forming the storage electrode 220 and an HSG silicon layer 225.

Referring to FIG. 2F, a portion of the fifth conductive layer 215 and the storage mask 208 may be removed by a CMP process, an etch back process, a combination process of CMP and etch back or any other method to expose the mold layer 220. Thus, the storage electrode 220 may be formed in the fifth contact hole 210. The storage electrode 220 may have a cylindrical shape. The storage electrode 220 is electrically connected to the first contact region 135.

When the portion of the fifth conductive layer 215 and the storage mask 208 are removed by the CMP process, it may be advantageous to use a slurry having an etching selectivity among oxides, polysilicon and silicon nitride. However, an oxide-based slurry including an abrasive of cerium dioxide (CeO₂) or silicon dioxide (SiO₂) may be also be used to remove the portion of the fifth conductive layer 215 and the storage mask 208.

A mixture gas that includes a first gas containing silicon and a second gas may be provided onto the storage electrode 220 as a source gas. The mixture gas may be provided onto the storage electrode 220 for about 10 to 20 minutes. The first gas containing silicon may further include hydrogen. The second gas may include an inactive gas. For example, the first gas may include a silane (SiH₄) gas or a disilane (Si₂H₆) gas, and the second gas may include a nitrogen (N₂) gas, a helium (He) gas and/or an argon (Ar) gas. As for the mixture gas employed for forming the HSG silicon layer 225, a volume ratio between the first gas and the second gas may be in a range of about 1.0:0.1 to 1.0:5.0. For example, when a volume of the first gas is in a range of about 50 to 1,000 cc, a volume of the second gas may be in a range of about 5 to 5,000 cc. Thus, an HSG silicon layer 225 may be advantageously uniformly formed on the storage electrode 220.

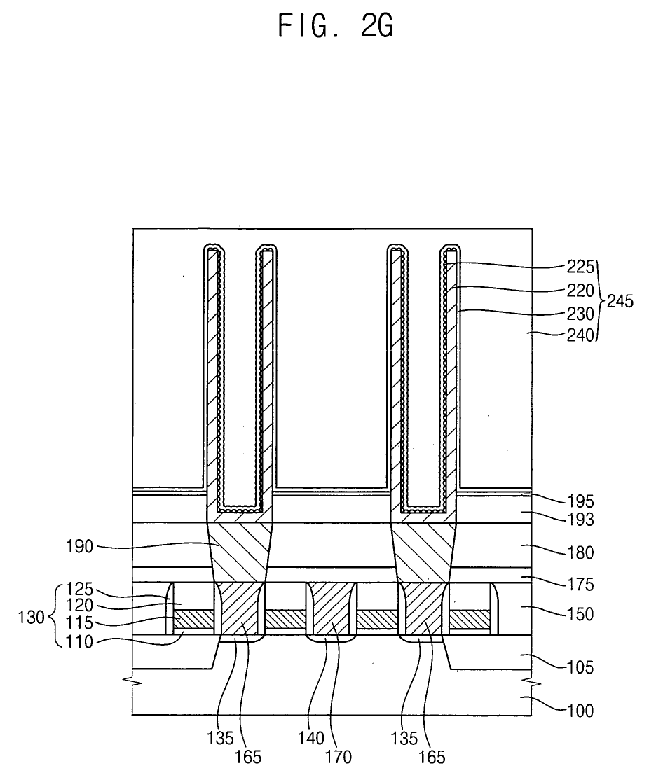

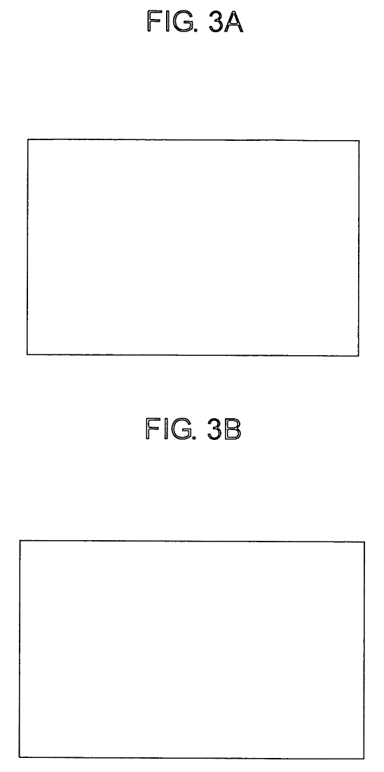

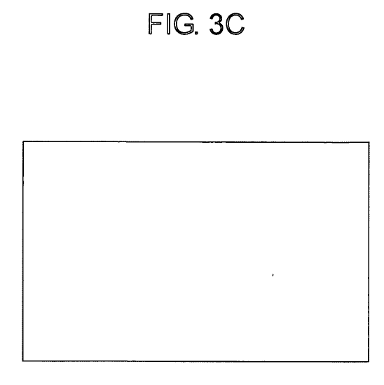

FIGS. 3A to 3C are electron microscopic pictures illustrating growths of the conventional HSG silicon layers relative to feeding times of source gases.

As shown in FIGS. 3A to 3C, an abnormal growth of an HSG silicon layer is augmented in accordance with an increase of the feeding time of a silane gas. When the HSG silicon layer is formed on a storage electrode using the silane gas or the disilane gas in accordance with a conventional method, the HSG silicon layer abnormally grows from the storage electrode and deteriorates both a structural stability of the storage electrode and electrical characteristics of the storage electrode. Particularly, when the HSG silicon layer grows abnormally at a lower portion of the storage electrode, the abnormally grown HSG silicon may be physically connected to each other, thereby causing an electrical defect of the storage electrode.

However, in some example embodiments of the present invention, when the HSG silicon layer 225 is formed on the storage electrode 220 using the mixture gas that includes the inactive gas and the silane gas or the disilane gas, the HSG silicon layer 225 exhibits grains of uniform sizes.

When the mixture gas including the inactive gas and the gas containing silicon is used as the source gas for forming the HSG silicon layer 225, a concentration difference of the source gas may be generated between an outside of the storage electrode 220 including polysilicon and an inside of the storage electrode 220. Thus, a growth of the HSG silicon layer 225 may be locally adjusted so that the grains of HSG silicon layer 225 do not grow abnormally and do not be physically connect to each other.

In some example embodiments of the present invention, increasing a process pressure of a reaction chamber for forming the HSG silicon layer 225 may cause a decrease in a deposition rate of the silane gas or the disilane gas for forming the HSG layer 225. Additionally, increasing the process pressure of the reaction chamber may cause a reduction in a mean free path of silane molecules or disilane molecules, thereby locally suppressing abnormal growths of the HSG grains at the lower portion of the storage electrode 220. The above technique may be used to further adjust grain sizes of the HSG silicon layer 225 thereby allowing for the HSG silicon layer 225 to be uniformly formed on the storage electrode 220.

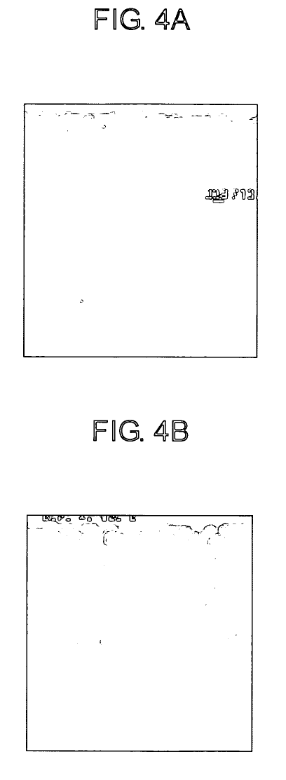

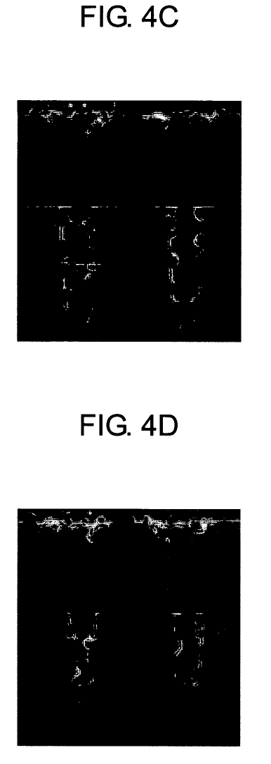

FIGS. 4A to 4D are electron microscopic pictures illustrating HSG silicon layer growth relative to volumes of inactive gases in accordance with example embodiments of the present invention. FIG. 4A shows a first HSG silicon layer formed using a silane gas, and FIG. 4B shows a second HSG silicon layer formed using a mixture gas including about 500 cc of silane gas and about 500 cc of nitrogen gas. FIG. 4C shows a third HSG silicon layer formed using a mixture gas including about 300 cc of silane gas and about 300 cc of nitrogen gas, and FIG. 4D shows a fourth HSG silicon layer formed using a mixture gas including about 300 cc of silane gas and about 600 cc of nitrogen gas.

Referring to FIG. 4A, the first HSG silicon layer grows abnormally from the storage electrode when the first HSG silicon layer is formed using the silane gas without the inactive gas. As shown in FIGS. 4B and 4C, however, when the second and the third HSG silicon layers are formed on the storage electrodes using the mixture gases, each having a volume ratio of about 1:1 between the silane gas and the nitrogen gas, the second and the third HSG silicon layers have reduced grain sizes and grow uniformly from the storage electrodes. As shown in FIG. 4D, when the fourth HSG silicon layer is formed on the storage electrode using the mixture gas having a volume ratio of about 1:2 between the silane gas and the nitrogen gas, the fourth HSG silicon layer includes grains that are not connected to each other at a lower portion of the storage electrode. Accordingly, increasing the volume ratio of the nitrogen gas in the mixture gas can be used to cause the grain size of the HSG silicon layer to decrease.

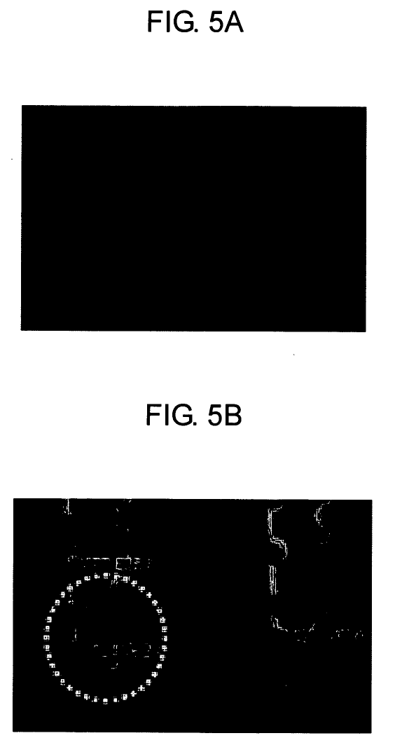

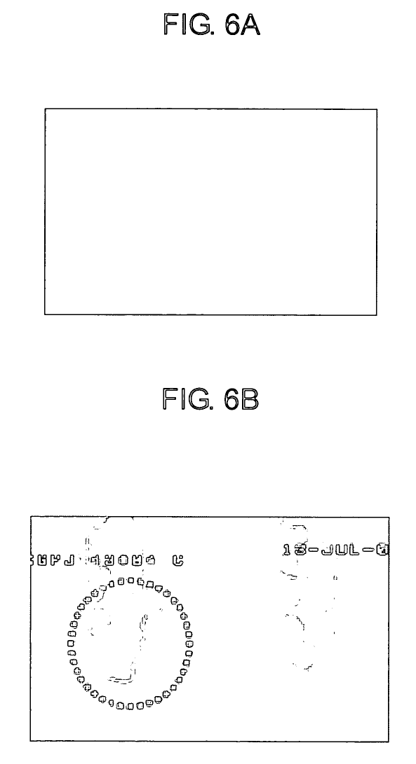

FIGS. 5A and 5B are electron microscopic pictures illustrating an HSG silicon layer formed by providing a mixture gas including a silane gas and a nitrogen gas for about 13 minutes in accordance with an example embodiment of the present invention. FIGS. 6A and 6B are electron microscopic pictures illustrating an HSG silicon layer formed by providing a mixture gas of a silane gas and a nitrogen gas for about 15 minutes in accordance with an example embodiment of the present invention.

Referring to FIGS. 5A and 5B, when the mixture gas including about 300 cc of silane gas and about 300 cc of nitrogen gas is provided onto a storage electrode for about 13 minutes, the HSG silicon layer is formed with grains having relatively small sizes. Moreover, a density of the grains in the HSG silicon layer is relatively low. As shown in FIGS. 6A and 6B, the HSG silicon layer may also be formed with grains having relatively small sizes and a relatively low density when the mixture gas is provided for about 15 minutes.

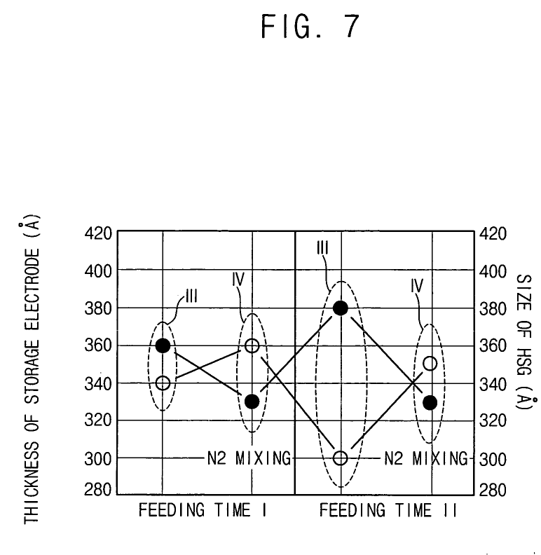

FIG. 7 is a graph illustrating thicknesses of storage electrodes and HSG silicon layers relative to feeding times of source gases in accordance with both a conventional method and example embodiments of the present invention. In FIG. 7, a first feeding time I is about 13 minutes, and a second feeding time II is about 15 minutes. In addition, “III” represents a first grain size of a first HSG silicon layer and a first thickness of a first storage electrode formed using only a silane gas per the conventional method, and “IV” indicates a second grain size of a second HSG silicon layer and a second thickness of a second storage electrode formed using a mixture gas including a silane gas and a nitrogen gas per example embodiments of the present invention. A symbol (∘) represents thickness of storage electrodes and a symbol (•) indicates sizes of HSGs.

As shown in FIG. 7, according to the conventional method, as the feeding time of the source gas increases, the first thickness of the first storage electrode and the first grain size in the first HSG silicon layer vary within a considerably large range. However, according to example embodiments of the present invention, although the feeding time of the source gas increases, a variation of the second grain size in the second HSG silicon layer is remarkably reduced. Therefore, in contrast to the conventional method, the second HSG silicon layer may be easily and uniformly formed and the second thickness of the second storage electrode may be adjusted with ease.

The HSG silicon layer according to example embodiments of the present invention may be advantageously employed in a DRAM device having nano-sized structures, as follows.

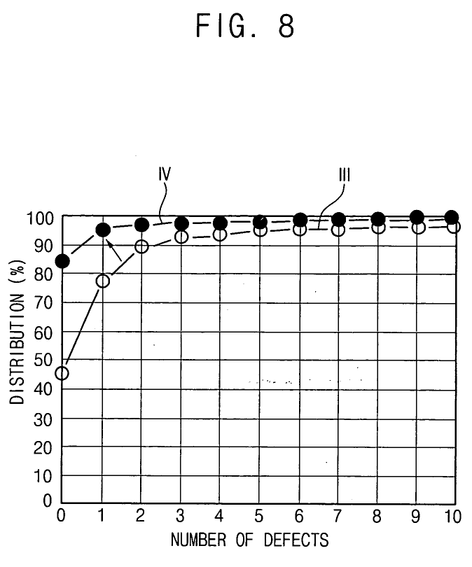

FIG. 8 is a graph illustrating accumulation distributions of electrical defects generated in capacitors having HSG silicon layers in accordance with example embodiments of the present invention. In FIG. 8, “III” represents an accumulation distribution of electrical defects generated in conventional capacitors, and “IV” indicates an accumulation distribution of electrical defects of capacitors according to the present invention.

As shown in FIG. 8, the number of electrical defects in the capacitors having the HSG silicon layers of the present invention greatly decreases in comparison with that of the conventional capacitors having the HSG silicon layers formed by the conventional method. That is, when the HSG silicon layer is formed using a mixture gas containing an inactive gas, a growth of the HSG silicon layer from a storage electrode may be suppressed and grain sizes of the HSG silicon layer may be advantageously controlled. Thus, the HSG silicon layer may be uniformly formed on the storage electrode and the electrical defects of the capacitor may be prevented.

FIG. 2G is a cross-sectional view illustrating steps of forming the capacitor 245.

Referring to FIG. 2G, the mold layer 200 may be removed by a dry etching process or a wet etching process, and the storage electrode 220 and the HSG silicon layer 225 are completed over the semiconductor substrate 100.

A dielectric layer 230 and a plate electrode 240 may be sequentially formed on an outer sidewall of the storage electrode 220 and on the HSG silicon layer 225 to complete the capacitor 245. The dielectric layer 230 may be formed using oxide, nitride, metal oxide, metal nitride or a mixture thereof. The plate electrode 240 may be formed using doped polysilicon, metal, metal oxide or metal nitride.

Although not shown, a fifth insulating interlayer may be formed on the capacitor 245 in order to insulate the capacitor 245 from an upper electrical wire. Thereafter, the upper electrical wire may be formed on the fifth insulating interlayer, thereby completing a semiconductor device. Also, a blocking layer may be additionally formed to protect the upper electrical wire.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A method of manufacturing a hemispherical grain (HSG) silicon layer comprising:
providing both a first gas including silicon and a second gas onto a surface to form the hemispherical grain silicon layer on the surface.

2. The method of claim 1, wherein the surface is a portion of a storage electrode.

3. The method of claim 2 further comprising:
forming a dielectric layer on the HSG silicon layer; and
forming a plate electrode on the dielectric layer;
whereby a capacitor is formed.

4. The method of claim 1, wherein the first gas comprises silane or disilane.

5. The method of claim 4, wherein the second gas comprises an inactive gas.

6. The method of claim 5, wherein the second gas comprises any one selected from the closed group consisting of a nitrogen (N₂) gas, a helium (He) gas and an argon (Ar) gas.

7. The method of claim 1, wherein a volume ratio between the first gas and the second gas is in a range of about 1.0:0.1 to about 1.0:5.0.

8. The method of claim 2, wherein the storage electrode has a cylindrical shape and the surface is an inside sidewall of the storage electrode.

9. The method of claim 3, wherein forming the storage electrode further comprises:
forming a pad electrically coupled to a contact region of a substrate;
forming a mold layer above the pad;
exposing at least a portion of the pad by forming a hole in the mold layer;
forming a conductive layer on the exposed portion of the pad, an inner sidewall of the hole and the mold layer; and
partially removing the conductive layer.

10. The method of claim 9, wherein forming the hole further comprises;
forming a mask layer on the mold layer; and
etching the mask layer to form a mask for defining the storage electrode on the mold layer.

11. A method of manufacturing a capacitor comprising;
forming a pad above a substrate having a contact region, the pad being electrically coupled to the contact region;
forming a storage electrode above the pad, the storage electrode being electrically coupled to the pad and the contact region;
forming a hemispherical grain (HSG) silicon layer on the storage electrode by providing both an inactive gas and a gas including silicon onto the storage electrode;
forming a dielectric layer on the HSG silicon layer; and
forming a plate electrode on the dielectric layer.

12. The method of claim 11, wherein the gas including silicon comprises a silane gas or a disilane gas.

13. The method of claim 12, wherein the inactive gas comprises a nitrogen gas, a helium gas or an argon gas.

14. The method of claim 13, wherein a volume ratio between the gas including silicon and the inactive gas is in a range of about 1.0:0.1 to about 1.0:5.0.

15. A method of manufacturing a semiconductor device comprising:
forming a contact region on a semiconductor substrate;
forming a pad above the contact region and electrically coupled to the contact region;
forming at least one insulating interlayer above the pad;
forming a mold layer above the insulating interlayer;
partially removing the mold layer and the insulating interlayer to form a contact hole exposing at least a portion of the pad;
forming a storage electrode above the pad and over an inner sidewall of the contact hole, the storage electrode being electrically coupled to the pad and the contact region;
forming a hemispherical grain (HSG) silicon layer on the storage electrode by providing an inactive gas and a gas including silicon and hydrogen onto the storage electrode;
forming a dielectric layer on the HSG silicon layer; and
forming a plate electrode on the dielectric layer;
whereby growth portions of grains of the HSG silicon layer located on a bottom portion of the storage electrode are not physically coupled to each other.

16. The method of claim 15, wherein the gas including silicon and hydrogen comprises a silane gas or a disilane gas.

17. The method of claim 16, wherein the inactive gas comprises a nitrogen gas, a helium gas or an argon gas.

18. The method of claim 17, wherein a volume ratio between the inactive gas and the gas including silicon and hydrogen is in a range of about 1.0:0.1 to about 1.0:5.0.

19. The method of claim 15 wherein the gas including silicon and hydrogen is provided onto the storage electrode for about 10 minutes or more.

20. The method of claim 15 wherein the growth portions of the grains of the HSG silicon layer located on the bottom portion of the storage electrode are substantially uniform in height.
